(19) United States
(12) Patent Application Publication
(10) Pub. No.: US 2025/0118618 A1
(43) Pub. Date: Apr. 10, 2025

(54) Packaging electronic device with liquid thermal interface material

(71) Applicant: Marvell Asia Pte Ltd, Singapore (SG)

(72) Inventors: Janak Patel, South Burlington, VT (US); Assaad El Helou, Los Angeles, CA (US)

(21) Appl. No.: 18/902,997

(22) Filed: Oct. 1, 2024

Related U.S. Application Data
(60) Provisional application No. 63/542,493, filed on Oct. 4, 2023.

(51) Int. Cl. H01L 23/367; H01L 23/00; H01L 23/24; H01L 23/373

(52) U.S. Cl. CPC H01L 23/3675; H01L 23/24; H01L 23/3736; H01L 24/29; H01L 24/32; H01L 24/83; H01L 24/16; H01L 24/33; H01L 24/73; H01L 2224/16155; H01L 2224/26175; H01L 2224/291; H01L 2224/32225; H01L 2224/33181; H01L 2224/73204; H01L 2224/73253; H01L 2224/83104

(57) ABSTRACT

An electronic device includes (i) an integrated circuit (IC) die mounted on a substrate, (ii) a lid having first and second surfaces facing one another, and one or more openings formed through the lid between the first and second surfaces, the lid being disposed over at least the IC die to form a space between the IC die and the first surface of the lid, the one or more openings are configured to enable transference of fluids through the lid, (iii) a liquid thermal interface material (TIM) filling the space and being formulated to conduct heat from the IC die to the lid, and (iv) a stopper structure extended from the first surface of the lid, the stopper structure includes one or more sidewalls configured to contain the liquid TIM at least in the space between the IC die and the first surface of the lid.

### CROSS-REFERENCE TO RELATED APPLICATIONS

This application claims the benefit of U.S. Provisional Patent Application 63/542,493, filed Oct. 4, 2023, whose disclosure is incorporated herein by reference.

### FIELD OF THE DISCLOSURE

The present invention relates generally to packaging of electronic devices, and particularly to methods and systems for improving heat dissipation from a package of one or more integrated circuit (IC) dies.

### BACKGROUND

Some electronic devices comprise one or more IC dies mounted on a substrate and packaged with a lid. Each of the IC dies typically comprises a front side with an active surface having integrated circuits, and a backside opposite the front side. For example, in a Flip Chip (FC) package, the front side is facing the substrate, and the backside is facing the lid. Such IC dies generate heat during operation, and therefore require dissipation of the heat, typically carried out through the backside of IC die and the lid. In order to improve heat dissipation, a thermal interface material (TIM) is typically disposed in a space between the lid and the backside of the IC die. Some TIMs are based on and selected from among polymers, graphite, indium solder alloy, and carbon nanotubes, but such TIMs may dissipate heat at an insufficiently high rate and/or the cost of these TIMs may exceed the budget of TIM in the FC-package.

TIM based on liquid metal can offer improved thermal performance at a reduced cost but can be difficult to implement in FC packages due to low viscosity and a melting point below room temperature. These properties of liquid metal TIM may result in leakage of the liquid metal TIM out of the space between the IC die and the lid, and the formation of a bubble of gas between the lid and the IC die thereby reducing the heat dissipation rate in FC packages.

The description above is presented as a general overview of related art in this field and should not be construed as an admission that any of the information it contains constitutes prior art against the present patent application.

### SUMMARY

An embodiment of the present invention that is described herein provides an electronic device including (i) an integrated circuit (IC) die mounted on a substrate, (ii) a lid having first and second surfaces facing one another, and one or more openings formed through the lid between the first and second surfaces, the lid being disposed over at least the IC die to form a space between the IC die and the first surface of the lid, the one or more openings are configured to enable transference of fluids through the lid, (iii) a liquid thermal interface material (TIM) filling the space and being formulated to conduct heat from the IC die to the lid, and (iv) a stopper structure extended from the first surface of the lid, the stopper structure including one or more sidewalls configured to contain the liquid TIM at least in the space between the IC die and the first surface of the lid.

In some embodiments, the one or more sidewalls of the stopper structure include one or more protrusions of the lid, the one or more protrusions being configured to at least partially surround the IC die. In other embodiments, the stopper structure includes a dam structure of a material separate from the lid, the one or more sidewalls of the dam structure being coupled to at least the first surface of the lid and being configured to at least partially surround the IC die. In yet other embodiments, the material of the dam structure includes an adhesive material.

In embodiments, some the electronic device includes a filling material disposed on the substrate at an edge of the IC die, at least one of the sidewalls is disposed (i) between the first surface of the lid and the filling material, and (ii) outside an area of the IC die. In other embodiments, at least one of the openings is formed along an axis between the at least one of the sidewalls and the edge of the IC die. In yet other embodiments, the lid has a first opening configured as a first conduit for inserting the liquid TIM into the space, and a second opening configured as a second conduit through which gas can flow out of the space.

In some embodiments, the lid has a single opening configured as a conduit for (i) inserting the liquid TIM into the space, and (ii) flowing the gas out of the space. In other embodiments, the electronic device includes a seal disposed at least on the second surface of the lid, the seal including at least an adhesive layer being configured to at least partially cover the one of the openings to block spillage of the liquid TIM out of the one of the openings. In yet other embodiments, the electronic device includes one or more plug seals disposed at least partly in the one or more openings, respectively, the one or more plug seals being configured to block spillage of the liquid TIM out of the one or more openings.

There is additionally provided, in accordance with an embodiment of the present invention, a method for fabricating an electronic device, the method includes mounting an integrated circuit (IC) die on a substrate. A lid having first and second surfaces facing one another, and one or more openings formed through the lid between the first and second surfaces for transference of fluids through the lid, is disposed over at least the IC die. The lid being disposed over at least the IC die to form a space between the IC die and the first surface of the lid. The space is filled with a liquid thermal interface material (TIM) formulated to conduct heat from the IC die to the lid. A stopper structure is formed and extended from the first surface of the lid, the stopper structure includes one or more sidewalls for containing the liquid TIM at least in the space between the IC die and the first surface of the lid.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device, in accordance with an embodiment that is described herein;

FIGS. 2-3 are schematic, bottom views showing operations for fabricating the electronic device of FIG. 1, in accordance with embodiments that are described herein;

FIGS. 4-5 are schematic top views of the electronic device of FIG. 1, in accordance with other embodiments that are described herein; and

FIG. 6 is a flow chart that schematically illustrates a method for fabricating the electronic device of FIG. 1, in accordance with an embodiment that is described herein.

### DETAILED DESCRIPTION OF EMBODIMENTS

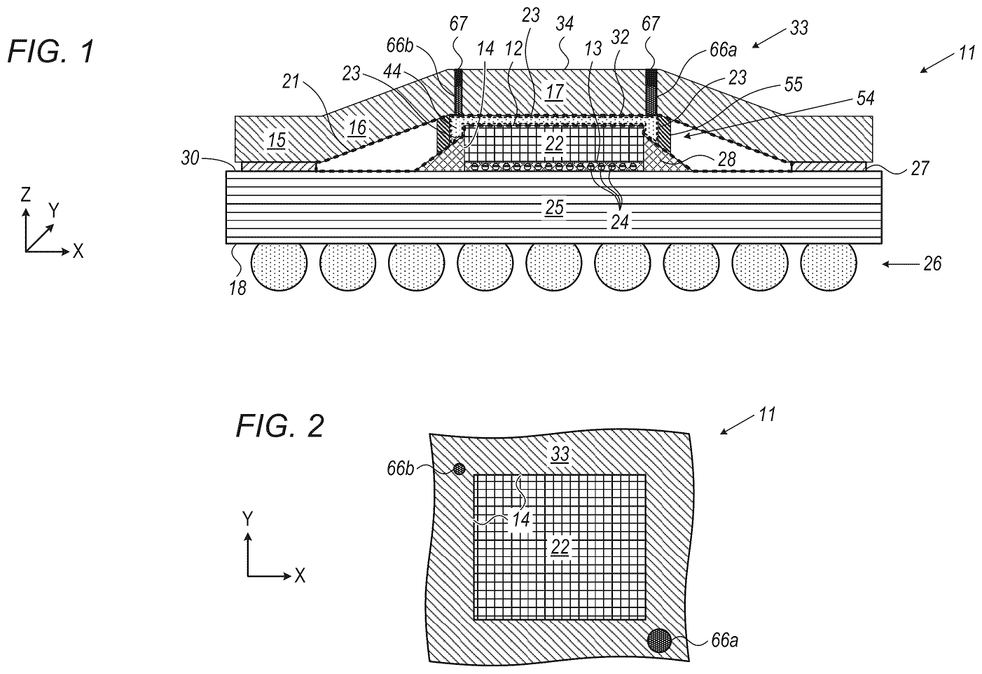

Embodiments of the present disclosure that are described herein provide techniques for improving heat dissipation from one or more integrated circuit (IC) dies assembled in a package. In some embodiments, an electronic device comprises a substrate, such as a laminated substrate, one or more IC dies mounted on the substrate, and a lid disposed over the substrate and the IC dies. Each of the IC dies comprises a front side with an active surface having integrated circuits, and a backside opposite the front side. In the present example, an IC die is packaged in a flip chip (FC) package, such as but not limited to a Flip Chip-Plastic Ball Grid Array (FC-PBGA) package, with the front side and backside of the IC die facing the substrate and lid, respectively. The FC package is described in detail in FIG. 1 below. In other examples, not shown, the IC die is packaged in other suitable lidded packages or other packages having suitable containment structures containing a thermal interface material that is not solid above room temperature.

In some embodiments, the electronic device comprises terminals, such as electrically conductive bumps disposed between the substrate and the front side of the IC die. The bumps are configured to exchange electrical signals between the substrate and the front side of the IC die. The electronic device further comprises a filling material disposed (i) between the bumps, and (ii) at the edges of the IC die. The filling material being configured to fix the IC die on the substrate and prevent mechanical damage to the bumps by absorbing compressive stress applied between the substrate and the IC die.

In some embodiments, the lid has first and second surfaces facing one another, and the electronic device comprises a liquid metal thermal interface material (TIM) disposed in a space between the first surface of the lid and the backside of the IC die. During operation, the IC die generates heat. The liquid metal TIM is formulated to conduct the heat from the backside of the IC die to the lid. It is noted that the liquid metal TIM is formulated to conduct the heat at a higher rate compared to that of other sorts of TIMs, such as but not limited to TIMs based on polymer, graphite or indium solder alloy.

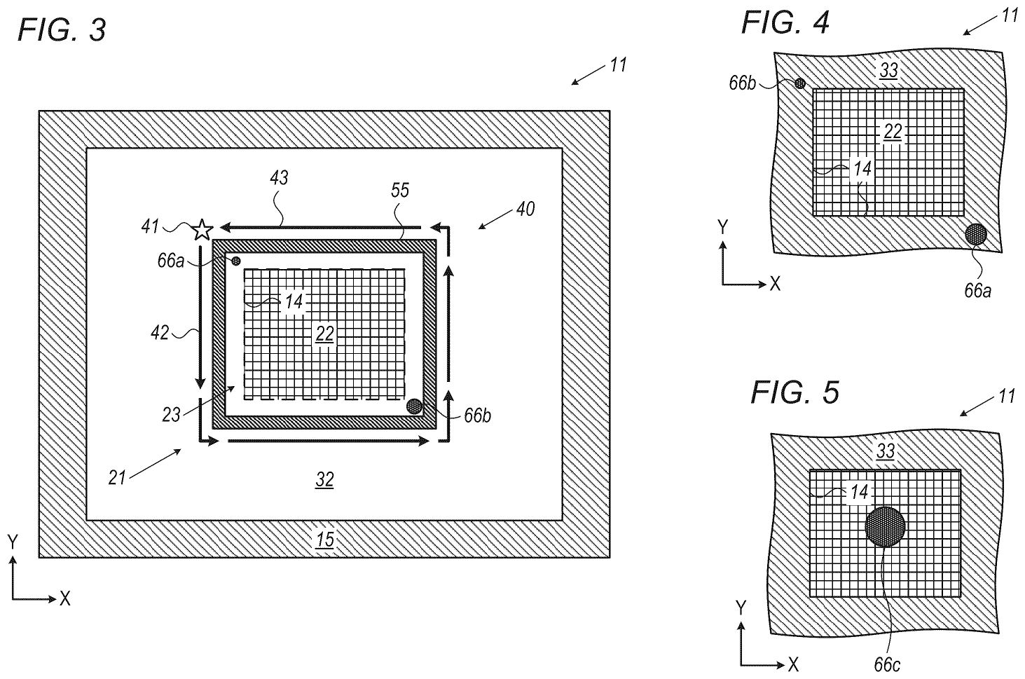

In some embodiments, the electronic device comprises a stopper structure extending from the first surface of the lid. The stopper structure comprises one or more sidewalls configured to contain the liquid TIM at least in the space between the IC die and the first surface of the lid. In some embodiments, the stopper structure comprises a dam structure of an adhesive material or any other suitable material different from (and/or separate from) the lid. In such embodiments, the one or more sidewalls of the dam structure are formed between (i) the filling material disposed at the edge of the IC die, and (ii) the first surface of the lid. The sidewalls are configured to at least partially surround the IC die. In other embodiments, the sidewalls comprise one or more protrusions of the lid that at least partially surround the IC die and are placed in contact with the filling material (as described above) or with the surface of the IC die facing the lid. The configurations of the stopper structures are described in detail in FIGS. 1 and 3 below.

In some embodiments, the lid has one or more openings formed through the lid between the first and second surfaces. In such embodiments, the one or more openings are configured to enable transference of fluids (e.g., liquid TIM and gas) through the lid, so as to entirely fill the space with the liquid metal TIM. Several configurations of the openings are described in detail in FIGS. 1-5 below.

The description above is presented as a general overview of embodiments of the present disclosure, which are described in detail herein.

FIG. 1 is a schematic, sectional view of an electronic device 11, in accordance with an embodiment that is described herein.

In some embodiments, electronic device 11 comprises a package substrate 25 (also referred to herein as a laminate substrate 25, or a laminated substrate 25, or a substrate 25) having surfaces 18 and 30 facing one another. Surface 18 of package substrate 25 is facing a printed circuit board (PCB, not shown). Electronic device 11 further comprises solder balls 26 soldered between surface 18 and the PCB and configured to exchange signals between substrate 25 and the PCB.

In some embodiments, electronic device 11 comprises electrically conductive bumps 24 disposed on surface 30 of substrate 25, and an integrated circuit (IC) die 22 disposed on bumps 24. IC die 22 has (i) a surface 13 facing substrate 25, (ii) edges 14 at the sides of IC die 22, and (iii) a surface 12 facing a lid 33 and a liquid metal thermal interface material (TIM) 44 that are described in detail below. Electronic device 11 further comprises a filling material 28 disposed (i) between surfaces 13 and 30 and between bumps 24, and (ii) at edges 14 of IC die 22. Filling material 28 being configured to fix IC die 22 on substrate 25 and to prevent mechanical damage to bumps 24 (e.g., distortion and/or breakage) by absorbing compressive stress applied between substrate 25 and IC die 22.

In some embodiments, lid 33 is made from nickel plated copper, or other suitable metallic material, and has (i) sections 15, 16, and 17, and (ii) surfaces 32 and 34 facing one another. In the present example, surface 32 faces substrate 25 and IC die 22, so that section 15 is disposed over substrate 25, section 17 is disposed over IC die 22, and section 16 is connecting between sections 15 and 17. Electronic device 11 further comprises an adhesive layer 27 disposed between surface 32 of lid 33 and surface 30 of substrate 25. In the present example, adhesive layer 27 comprises epoxy SE4450 produced supplied by DuPont (974 Centre Rd, Wilmington, DE 19805) having a thickness between about 50 μm and 200 μm and configured to adhere lid 33 to substrate 25.

In some embodiments, electronic device 11 has (i) a gap 21 formed between (a) lid 33 and (b) substrate 25 and IC die 22, and (ii) a space 23, which is a sub-volume within gap 21, space 23 is configured to contain liquid metal TIM 44. In some embodiments, electronic device 11 comprises a stopper structure 54 configured to contain liquid metal TIM 44 within space 23. Stopper structure 54 has one or more sidewalls extended from surface 32 of lid 33 and described in detail below.

In some embodiments, stopper structure 54 comprises a dam structure 55 of an adhesive material, such as silicon-based Sylgard 577 supplied by Elsworth Adhesives (W129 N10825 Washington Drive Germantown, WI 53022), or silicon-based EA 6900 supplied by DowDupont™ (974 Centre Rd, Wilmington, DE 19805). In such embodiments, dam structure 55 is formed between (i) the surface of filling material 28 disposed at edges 14 of IC die 22, and (ii) surface 32 of lid 33. Dam structure 55 is configured to at least partially (and typically fully) surround IC die 22.

In other embodiments, instead of dam structure 55, stopper structure 54 comprises one or more protrusions (not shown) extending from lid 33 and contacting filling material 28, in a manner similar to that described for dam structure 55 above. It is noted that in the present example dam structure 55 extends out of edges 14 of IC die 22 (along at least one of the X- and Y-axes) and the area of stopper structure 54 in XY plane is larger than that of IC die 22. This configuration will be described in more detail in FIGS. 2 and 3 below. In alternative embodiments, the sidewalls of dam structure 55 may be disposed on surface 12 of IC die 22, or at any other suitable location within gap 21.

In the context of the present disclosure and in the claims, the term space refers to the volume bounded between (i) surfaces 12 and 32, (ii) the sidewalls of stopper structure 54 (e.g., dam structure 55, or the protrusions of lid 33), and (iii) the surface of filling material 28 and edges 14 of IC die 22.

In the present example, TIM 44 is made from liquid metal, such as the Liquid Metal TIM 300E product supplied by Indium Corporation (301 Woods Park Drive, Suite 301, Clinton, NY 13323, USA or from any other suitable material. In the context of the present disclosure and in the claims, the term liquid metal refers to any suitable metal or metal alloy whose melting temperature is less than room temperature (i.e., less than 25° C.). In alternative embodiments, the melting temperature of TIM 44 may be higher than room temperature. In the present example, liquid metal TIM 44 has a thermal conductivity of about 44 W/m-K, which is greater than the thermal conductivity of other TIMs, such as but not limited to TIMs based on polymers, graphite or indium solder alloy. It is noted that greater thermal conductivity of the TIM improves the dissipation rate of heat (generated by IC die 22) compared to that of the TIMs based on the other materials described above.

In some embodiments, lid 33 is formed with one or more openings 66, in the present example, openings 66a and 66b formed through lid 33 between surfaces 34 and 32. In such embodiments, opening 66a is configured to enable transference of liquid metal TIM 44 through lid 33 into space 23 and entirely filling space 23 with liquid metal TIM 44. Opening 66b is configured to allow gas (e.g., air and/or gas evaporating from the liquid metal TIM) to flow out of space 23. As such, openings 66a and 66b are configured to enable transference of fluids (liquids and gas) through lid 33. It is noted that openings 66a and 66b are positioned between (i) the sidewalls of dam structure 55, and (ii) edges 14 of IC die 22. This configuration allows elimination of a gas bubble from forming in space 23 between IC die 22 and lid 33, as will be described in detail in FIG. 2 below.

In the present example, openings 66a and 66b have a circular cross section in XY plain, with a diameter between about 1 mm and 5 mm in an embodiment. In this example, opening 66a is configured as a first conduit for inserting liquid metal TIM 44 into space 23, and therefore has a diameter larger than that of opening 66b, which is configured as a second conduit through which the gas can flow out of the space 23. It is noted that the insertion of at least a portion of liquid metal TIM 44 into space 23 is carried out by injecting liquid metal TIM 44 through opening 66a, for instance using a pressure greater than 1 atmosphere.

In alternative embodiments, at least one of openings 66a and 66b may have any other suitable shape, such as a rectangular or elliptical cross section in XY plain and/or a variable width of the conduit along the Z-axis.

In some embodiments, electronic device 11 comprises one or more plug seals 67 disposed at least partly in at least one of (and typically both) openings 66a and 66b. Plug seals 67 are made from a suitable metal, e.g., copper having a coefficient of thermal expansion (CTE) similar to that of lid 33. Plug seals 67 are configured to block spillage of liquid metal TIM 44 out of openings 66a and 66b. In other embodiments, in addition to or instead of plug seals 67, an adhesive material such as Sylgard 577 (described above) may be used for sealing at least one of openings 66a and 66b. In yet other embodiments, a seal layer (not shown) may be disposed at least on the surface 34 of lid 33, the seal layer comprising at least an adhesive layer (e.g., Sylgard 577) being configured to at least partially (and typically fully) cover openings 66a and 66b to block spillage of liquid metal TIM 44 out of openings 66a and 66b.

FIG. 2 is a schematic, bottom view of an operation for fabricating openings 66a and 66b of electronic device 11, in accordance with an embodiment that is described herein. In the present example, at least section 17 of lid 33, plug seals 67, and liquid metal TIM 44 have been removed from the bottom view of electronic device 11 to show the position of openings 66a and 66b relative to IC die 22.

In some embodiments, openings 66a and 66b are fabricated by drilling respective conduits through lid 33. It is noted that the diameter of opening 66a is greater than that of opening 66b, as described in FIG. 1 above. In the present example, openings 66a and 66b are positioned outside the area bounded by edges 14 of IC die 22, i.e., outside the area of IC die 22. In this configuration, in case of a gas (e.g., air) bubble is trapped (or formed due to outgassing) in TIM 44 within the volume of space 23, the bubble will be moved by the heat generated by IC die 22 into openings 66a and/or 66b. Thus, the gas bubble does not buffer between IC die 22 and lid 33, and therefore, does not interfere with the dissipation heat between IC die 22 and lid 33.

FIG. 3 is a schematic, bottom view of an operation for fabricating dam structure 55 of electronic device 11, in accordance with another embodiment that is described herein. In the present example, sections 17 and 16 of lid 33, plug seals 67, and liquid metal TIM 44 have been removed from the bottom view of electronic device 11 to show the position of dam structure 55 relative to the intended location of IC die 22 (shown in dashed lines because lid 33 is not yet place over IC die 22) and the actual position of openings 66a and 66b. Moreover, in the example of FIG. 3 lid 33 is flipped and shows gap 21 and space 23, and the fabrication of dam structure 55 is carried out before placing lid 33 over substrate 25 and IC die 22.

In some embodiments, the fabrication of dam structure 55 is carried out after drilling openings 66a and 66b. Dam structure 55 is fabricated by dispensing adhesive material (e.g., Sylgard 577 described in FIG. 1 above) on surface 32 along a path 40 surrounding openings 66a and 66b, and the intended position of IC die 22. In the present example, path 40 has a square shape, but in other embodiments path 40 may have a rectangular shape or any other suitable shape, depending on the shape of IC die 22.

In some embodiments, the application of the adhesive material along path 40 begins at a location 41 with dispensing the adhesive material along an arrow 42. The dispensing is carried out continuously in a counterclockwise direction and ends with an arrow 43 that terminates at point 41. In other embodiments, the application of the adhesive material may be carried out along path 40 using any other suitable direction (e.g., clockwise), or using any other suitable technique (other than dispensing) to fabricate dam structure 55.

FIG. 4 is a schematic top view of a portion of electronic device 11, in accordance with another embodiment that is described herein. It is noted that at least a portion of section 17 of lid 33 has been removed from the top view of electronic device 11 to show the position of openings 66a and 66b relative to IC die 22.

In some embodiments, openings 66a and 66b are formed within the area bounded by edges 14 of IC die 22, i.e., within the area of IC die 22. It is noted that dam structure 55 (not shown) is configured to surround both IC die 22 and openings 66a and 66b, as shown and described in detail in FIGS. 1 and 3 above.

In alternative embodiments, one of openings 66a and 66b may be formed outside the area bounded by edges 14 of IC die 22.

FIG. 5 is a schematic top view of a portion of electronic device 11, in accordance with an alternative embodiment that is described herein. It is noted that at least a portion of section 17 of lid 33 has been removed from the top view of electronic device 11 to show the position of an opening 66c relative to IC die 22.

In some embodiments, instead of openings 66a and 66b, electronic device 11 has a single opening 66c formed through lid 33. In the present example, opening 66c is formed within the area bounded by edges 14 of IC die 22, e.g., at the center of IC die 22 in XY plain. Opening 66c is configured as a conduit both for (i) inserting liquid metal TIM 44 into space 23, and (ii) flowing the gas out of space 23. As such, in the present example opening 66c has a diameter between about 3 mm and 5 mm depending on the viscosity of liquid metal TIM 44 at room temperature. In other words, higher viscosity of liquid metal TIM 44 in room temperature requires a larger diameter of opening 66c that could be even larger than about 5 mm.

In other embodiments, opening 66c may be formed in lid 33 at any other position, either within the area bounded by edges 14 (as shown in FIGS. 2 and 3 above), or outside the area bounded by edges 14 (as shown in FIG. 4 above.

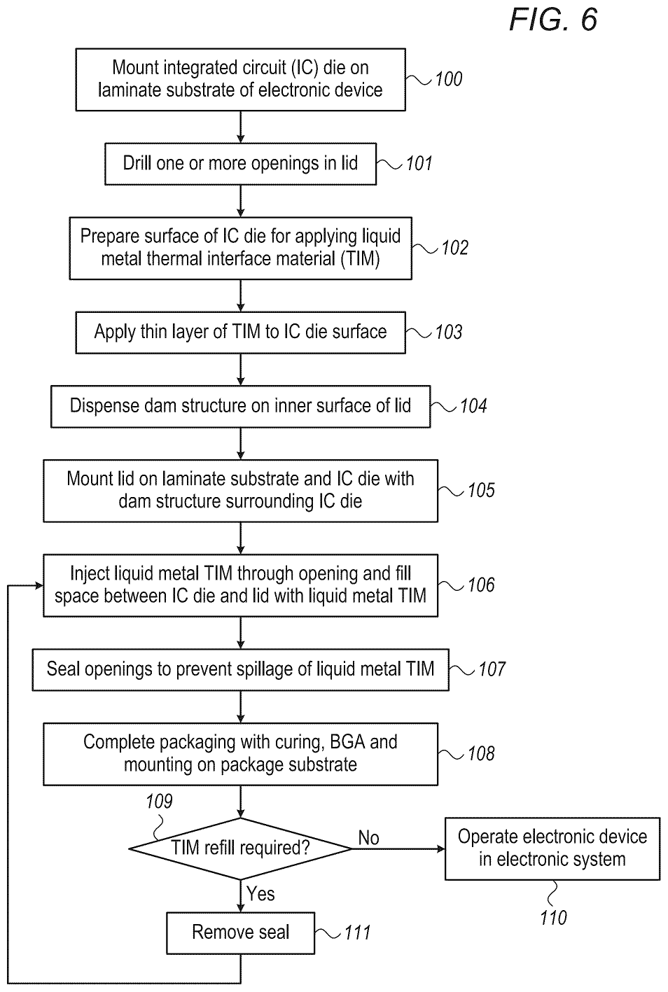

FIG. 6 is a flow chart that schematically illustrates a method for fabricating electronic device 11, in accordance with an embodiment that is described herein.

The method begins at an IC die mounting operation 100, with disposing IC die 22 and bumps 24 on package substrate 25 and applying filling material 28 (i) between IC die 22 and package substrate 25, and (ii) at the edges 14 of IC die 22, as described in detail in FIG. 1 above.

At an opening formation operation 101, openings 66a and 66b (e.g., having a diameter between about 1 mm and 5 mm) are formed by drilling through lid 33 at opposite corners outside the intended area of IC die 22, as shown and described in detail in FIG. 1 above. In other embodiments, any other suitable number of openings 66 (e.g., one opening as shown in FIG. 5 above, or more than two opening) may be drilled through lid 33 in operation 101. The number of openings is determined based on various considerations, such as but not limited to: (i) the size of IC die 22 in XY plain, (ii) the intended thickness of liquid metal TIM 44 along the Z axis, and (iii) the application and required rate of heat dissipation from IC die 22.

At a surface preparation operation 102, surface 12 of IC die 22 being prepared for applying liquid metal TIM 44. The surface preparation comprises, for example, an etching process (wet and/or dry) to clean surface 12 from foreign materials, and in some cases to adjust the roughness of surface 12 to obtain improved adhesion between surface 12 and liquid metal TIM 44.

At a first TIM application operation 103, a thin film (e.g., having a thickness between about 1 μm and 5 μm) of liquid metal TIM 44 is applied to surface 12 of IC die 22. In some embodiments, operation 103 is carried out using a brush or any other suitable TIM application technique. In such embodiments, the thin film of liquid metal TIM 44 is formulated to break the surface tension in surface 12, so as to reduce the required pressure for injecting liquid metal TIM 44 through opening 66a after disposing lid 33 over IC die 22, as will be described below. It is noted that applying the thin film is not an absolute requirements, so that in other embodiments, in case the adhesion between liquid metal TIM 44 and surface 12 is sufficiently high, operation 103 may be removed from the method.

At a dam structure formation operation 104, dam structure 55 is formed by dispensing adhesive material (e.g., Sylgard 577, or EA6900) on surface 32 of lid 33, as described in detail in FIG. 3 above. In the present example, the adhesive material of dam structure 55 is intended to be coupled with the surface of filling material 28, as shown in FIG. 1 above. Alternately, the dam structure 55 can be formed by dispensing adhesive material on the surface of filling material 28.

At a lid mounting operation 105, lid 33 is disposed on package substrate 25 and IC die 22 with dam structure 55 surrounding IC die 22 as shown in FIGS. 1 and 3 above.

At a second TIM application operation 106, liquid metal TIM 44 being injected through opening 66a at a pressure greater than 1 atmosphere to fill space 23. In some embodiments, liquid metal TIM 44 being disposed within space 23 over the thin film of liquid metal TIM 44 (applied at operation 103 above). In such embodiments, liquid metal TIM 44 fills space 23 between IC die 22 and surface 32 of lid 33, as described in detail in FIG. 1 above. Additionally, or alternatively, liquid metal TIM 44 may be applied to fill space 23 using other suitable techniques, such as but not limited to (i) applying liquid metal TIM 44 to fill space 23 using gravity, (ii) placing electronic device 11 on a rotatable table and spinning electronic device 11 about the Z-axis to fill space 23 with liquid metal TIM 44 and remove gas bubbles, (iii) placing electronic device 11 on a table configured to apply vibrations to fill space 23 with liquid metal TIM 44 and remove gas bubbles, (iv) applying vacuum to space 23 while inserting (e.g., injecting) liquid metal TIM 44 through opening 66a, or any other suitable technique.

At a sealing operation 107, openings 66a and 66b being sealed using plug seals 67 to prevent spillage of liquid metal TIM 44 out of space 23, as described in detail in FIG. 1 above. In some embodiments, an adhesive sealing material (e.g., Sylgard 577) may be disposed to close openings 66a and 66b instead of or in addition to plug seals 67, and after concluding the sealing application, wiping residues of the Sylgard 577 from surface 34 of lid 33.

At a final assembling operation 108, a set of processes is carried out to complete the packaging of IC die 22. In the present example, the set of processes comprises curing at predefined temperatures and time intervals, soldering balls 26 (e.g., in a solder reflow operation) to surface 18 of package substrate 25, and coupling the PCB (or any other suitable substrate) to solder balls 26, as described in FIG. 1 above. Additionally, or alternatively, operation 106 may be carried out after the curing process or after soldering balls 26 to package substrate 25 and/or after coupling solder balls 26 to the PCB. In other embodiments, in case of liquid metal TIM 44 being injected after solder balls 26 being soldered on to the PCB, during the testing operation of the Flip chip plastic ball grid array (FC-PBGA) space 23 is filled with Deionized water (DI water) to accommodate heat transfer from IC die 22 to lid 33. Subsequently, the DI water (not shown) is evaporated after the testing operation due to the heat generated by IC die 22 (or in another operation of the fabrication process).

At a decision operation 109, the filling level of liquid metal TIM 44 in space 23 is checked using any suitable technique, such as ultrasound or acoustic microscope, to detect whether a bubble of gas (e.g., air) is trapped within space 23. It is noted that the aforementioned ultrasound testing is carried out before implementing electronic device 11 in an electronic system. Additionally, or alternatively, insufficient heat dissipation rate (e.g., lower than specified) during the operation (or testing) of electronic device 11, may be indicative of insufficient filling level of liquid metal TIM 44 in space 23.

In case the filling level of liquid metal TIM 44 in space 23 is proper (as shown in FIG. 1 above), the method proceeds to a final operation 110 that concludes the method, with electronic device 11 being (integrated and) operated in an electronic system (not shown).

In case the filling level of liquid metal TIM 44 in space 23 is improper, the method proceeds to a plug seal removal operation 111 with the removal of plug seals 67 at least out of opening 66a, and the method loops back to operation 106.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
an integrated circuit (IC) die mounted on a substrate;
a lid having first and second surfaces facing one another, and one or more openings formed through the lid between the first and second surfaces, the lid being disposed over at least the IC die to form a space between the IC die and the first surface of the lid, wherein the one or more openings are configured to enable transference of fluids through the lid;
a liquid thermal interface material (TIM) filling the space and being formulated to conduct heat from the IC die to the lid; and
a stopper structure extended from the first surface of the lid, the stopper structure comprising one or more sidewalls configured to contain the liquid TIM at least in the space between the IC die and the first surface of the lid.

2. The electronic device according to claim 1, wherein the one or more sidewalls of the stopper structure comprise one or more protrusions of the lid, the one or more protrusions being configured to at least partially surround the IC die.

3. The electronic device according to claim 1, wherein the stopper structure comprises a dam structure of a material separate from the lid, the one or more sidewalls of the dam structure being coupled to at least the first surface of the lid and being configured to at least partially surround the IC die.

4. The electronic device according to claim 3, wherein the material of the dam structure comprises an adhesive material.

5. The electronic device according to claim 1, comprising a filling material disposed on the substrate at an edge of the IC die, wherein at least one of the sidewalls is disposed (i) between the first surface of the lid and the filling material, and (ii) outside an area of the IC die.

6. The electronic device according to claim 5, wherein at least one of the openings is formed along an axis between the at least one of the sidewalls and the edge of the IC die.

7. The electronic device according to claim 1, wherein the lid has a first opening configured as a first conduit for inserting the liquid TIM into the space, and a second opening configured as a second conduit through which gas can flow out of the space.

8. The electronic device according to claim 1, wherein the lid has a single opening configured as a conduit for (i) inserting the liquid TIM into the space, and (ii) flowing the gas out of the space.

9. The electronic device according to claim 1, comprising a seal disposed at least on the second surface of the lid, the seal comprising at least an adhesive layer being configured to at least partially cover the one of the openings to block spillage of the liquid TIM out of the one of the openings.

10. The electronic device according to claim 1, comprising one or more plug seals disposed at least partly in the one or more openings, respectively, the one or more plug seals being configured to block spillage of the liquid TIM out of the one or more openings.

11. A method for fabricating an electronic device, the method comprising:
mounting an integrated circuit (IC) die on a substrate;
disposing, over at least the IC die, a lid having first and second surfaces facing one another, and one or more openings formed through the lid between the first and second surfaces for transference of fluids through the lid, the lid being disposed over at least the IC die to form a space between the IC die and the first surface of the lid;
filling the space with a liquid thermal interface material (TIM) formulated to conduct heat from the IC die to the lid; and
forming a stopper structure extended from the first surface of the lid, the stopper structure comprising one or more sidewalls for containing the liquid TIM at least in the space between the IC die and the first surface of the lid.

12. The method according to claim 11, wherein forming the one or more sidewalls of the stopper structure comprise forming one or more protrusions of the lid that at least partially surround the IC die.

13. The method according to claim 11, wherein forming the stopper structure comprises forming a dam structure of a material separate from the lid, and coupling the one or more sidewalls of the dam structure, which at least partially surround the IC die, to at least the first surface of the lid.

14. The method according to claim 13, wherein forming the dam structure comprises dispensing an adhesive material on the first surface of the lid.

15. The method according to claim 11, comprising disposing a filling material on the substrate at an edge of the IC die, wherein forming the sidewalls comprises disposing at least one of the sidewalls (i) between the first surface of the lid and the filling material, and (ii) outside an area of the IC die.

16. The method according to claim 15, wherein forming the one or more openings comprises forming at least one of the openings along an axis between the at least one of the sidewalls and the edge of the IC die.

17. The method according to claim 11, wherein forming the one or more openings comprises forming in the lid a first opening for inserting the liquid TIM into the space, and a second opening for flowing the gas out of the space.

18. The method according to claim 11, wherein forming the opening comprises forming in the lid a single opening for (i) inserting the liquid TIM into the space, and (ii) flowing the gas out of the space.

19. The method according to claim 11, comprising disposing a seal at least on the second surface of the lid, the seal comprising at least an adhesive layer for at least partially covering the one of the openings to block spillage of the liquid TIM out of the one of the openings.

20. The method according to claim 11, wherein disposing the seal comprises disposing one or more plug seals at least partly in the one or more openings, respectively, for blocking spillage of the liquid TIM out of the one or more openings.
